(19) United States
(12) Patent Application Publication
(10) Pub. No.: US 2005/0005847 A1
(43) Pub. Date: Jan. 13, 2005

(54) Semiconductor processing system and semiconductor carrying mechanism

(76) Inventor: Tsutomu Hiroki, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/500,966

(22) PCT Filed: Jan. 7, 2003
(86) PCT No.: PCT/JP03/00039

(30) Foreign Application Priority Data
Jan. 8, 2002 (JP) 2002-001831

(51) Int. Cl. C23C 16/00

(52) U.S. Cl. 118/719

(57) ABSTRACT

A semiconductor processing system, wherein a carrying base table 30 is installed in a carrying mechanism 26 for carrying a processed substrate W to a processing device, first and second holing arms 32A and 32B are slidably installed parallel with each other on the carrying base table 30, and the first and second support arms 32A and 32B having first and second holding surfaces 33A and 33B for holding the processed substrate W are substantially positioned on the same plate and operated so that the first and second holding surfaces 33A and 33B can be projected in the same direction relative to the carrying base table 30.

### FIELD OF THE INVENTION

The present invention relates to a transfer mechanism for use in a semiconductor processing system for transferring a substrate to be processed such as a semiconductor wafer relative to a processing apparatus and a semiconductor processing system having the transfer mechanism. A term semiconductor processing used herein denotes various processes performed to manufacture semiconductor devices or a structure connected to semiconductor devices, e.g., wiring and electrodes, on a substrate to be processed such as a semiconductor wafer or an LCD substrate by way of forming a semiconductor layer, an insulating layer, a conductive layer and the like on the substrate to be processed into a required pattern.

### BACKGROUND OF THE INVENTION

In order to manufacture a semiconductor integrated circuit, various processes such as film forming, etching, oxidation and diffusion are performed on a wafer. In such processes, a throughput and a yield are required to be improved along with the trend of miniaturization and high integration of the semiconductor integrated circuit. From this point of view, a semiconductor processing system made into a so-called cluster tool has been known, wherein a plurality of processing apparatuses performing a same process or a plural number of processing apparatuses performing different processes are connected with one another via a common transfer chamber such that various processes can be successively executed without exposing a wafer to the atmosphere. A cluster tool type semiconductor processing system is disclosed in, e.g., Japanese Patent Laid-open Publication Nos. 3-19252, 2000-208589 and 2000-299367. An assignee of the present invention also filed a patent application on an improved cluster tool type semiconductor processing system (Patent Application No. 2001-060968).

Disposed in a common transfer chamber of such a semiconductor processing system is a transfer mechanism for transferring a substrate to be processed such as a wafer relative to a processing apparatus. Frog leg type two multi-joint arms, installed in two vertical steps, and capable of bending, stretching, revolving, and moving up and down have been known as one example of the transfer mechanism. The two multi-joint arms are used to exchange a processed wafer for an unprocessed wafer by directly accessing the processing apparatus. Specifically, the processed wafer is unloaded from the inside of the processing apparatus with one empty multi-joint arm and then the unprocessed wafer held in the other multi-joint arm is loaded into the processing apparatus. Further, two multi-joint arms capable of bending and stretching in opposite directions in a same plane have been known as another example of the transfer mechanism.

The main concern of the aforementioned transfer mechanism has been mainly put on operations of bending, stretching and revolving an arm and, thus, positioning accuracy, reproducibility of the positioning accuracy, reliability or maintainability is open to further improvement. Additionally, a transfer robot in which a wafer supporting portion moves along a linear track is disclosed in Japanese Patent Laid-open Publication No. 10-50804. However, this transfer robot suffers from a throughput problem.

### SUMMARY OF THE INVENTION

It is, therefore, an object of the present invention to improves positioning accuracy, reproducibility of the positioning accuracy or a throughput in a transfer mechanism of a semiconductor processing system.

In accordance with one aspect of the invention, there is provided A transfer mechanism for transferring substrates to be processed relative to a processing apparatus in a semiconductor processing system, the transfer mechanism including a transfer base; and a first and a second support arm slidably installed side by side on the transfer base, wherein the first and the second support arm respectively have a first and a second support surface for holding the substrates to be processed; the first and the second support surface are positioned on a substantially same plane; and the first and the second support arm are operated such that the first and the second support surface are projected from the transfer base toward a substantially equivalent side.

In accordance with another aspect of the invention, there is provided A transfer mechanism for transferring substrates to be processed relative to a processing apparatus in a semiconductor processing system, the transfer mechanism including a linearly movable moving table; a transfer base connected to the moving table via a coupling axis, the transfer base being revolvable relative to the moving table with the coupling axis being a center of revolution; and a first and a second support arm slidably installed side by side on the transfer base, wherein the first and the second support arm respectively have a first and a second support surface for holding the substrates to be processed; the first and the second support surface are positioned on a substantially same plane; and the first and the second support arm are operated such that the first and the second support surface are projected from the transfer base toward a substantially equivalent side.

In accordance with still another aspect of the invention, there is provided A semiconductor processing system including a common transfer chamber; a plurality of processing apparatuses connected in parallel to the common transfer chamber; and a transfer mechanism, disposed in the common transfer chamber, for transferring substrates to be processed relative to the processing apparatuses, wherein the transfer mechanism has a revolvable transfer base; and a first and a second support arm slidably installed side by side on the transfer base, wherein the first and the second support arm respectively have a first and a second support surface for holding the substrates to be processed; the first and the second support surface are positioned on a substantially same plane; and the first and the second support arm are operated such that the first and the second support surface are projected from the transfer base toward a substantially equivalent side.

### BRIEF DESCRIPTION OF THE DRAWINGS

FIG. 1 shows a schematic plan view of a semiconductor processing system using a transfer mechanism in accordance with a first embodiment of the present invention;

FIG. 2 illustrates an enlarged perspective view of the transfer mechanism shown in FIG. 1;

FIG. 3 describes a perspective view showing an internal structure of the transfer mechanism shown in FIG. 1;

FIGS. 4A to 4F offer plan views illustrating an operation of the transfer mechanism shown in FIG. 1;

FIGS. 5A to 5C provide plan views illustrating an exemplary modification of an operation for exchanging semiconductor wafers W by using the transfer mechanism shown in FIG. 1;

FIGS. 6A to 6C present plan views illustrating another exemplary modification of an operation for exchanging the semiconductor wafers W, which is performed by using the transfer mechanism shown in FIG. 1;

FIG. 7 depicts a perspective view showing an exemplary modification of a driving unit of a support arm in the transfer mechanism shown in FIG. 1;

FIG. 8 represents a schematic plan view showing an exemplary modification of a semiconductor processing system;

FIG. 9 sets forth a schematic plan view showing a semiconductor processing system using a transfer mechanism in accordance with a second embodiment of the present invention;

FIG. 10 illustrates a perspective view showing a conjugated state of a transfer base and a moving table in the transfer mechanism shown in FIG. 9;

FIG. 11 describes a perspective view illustrating an operation for exchanging semiconductors wafer W, which is performed by using the transfer mechanism shown in FIG. 9;

FIG. 12 offers an exploded perspective view showing an internal structure of a transfer mechanism in accordance with a third embodiment of the present invention;

FIG. 13 schematically depicts a connected state of gear mechanisms in the transfer mechanism shown in FIG. 12;

FIG. 14 describes a relationship between a spline axis and a gear in the transfer mechanism illustrated in FIG. 12;

FIG. 15 is an enlarged perspective view showing an exemplary modification of the transfer mechanism;

FIGS. 16A to 16E provide plan views illustrating an operation for exchanging semiconductor wafers W, which is performed by using the transfer mechanism illustrated in FIG. 15;

FIG. 17 presents an exploded perspective view showing an internal structure of a transfer mechanism in accordance with a fourth preferred embodiment of the present invention;

FIGS. 18A to 18E represent plan views illustrating an operation for exchanging semiconductor wafers W, which is performed by using the transfer mechanism depicted in FIG. 17;

FIG. 19 describes an enlarged perspective view showing an exemplary modification of the transfer mechanism;

FIGS. 20A and 20B provide schematic plan views showing a semiconductor processing system using the transfer mechanism illustrated in FIG. 19;

FIG. 20C presents a schematic plan view illustrating another semiconductor processing system using the transfer mechanism shown in FIG. 19;

FIGS. 21A and 21B depict schematic plan views showing still another semiconductor processing system using the transfer mechanism shown in FIG. 19; and

FIGS. 22A, 22B and 23 offer perspective views illustrating a common transfer chamber for explaining related arts.

### DETAILED DESCRIPTION OF THE PREFERRED EMBODIMENTS

Hereinafter, preferred embodiments of the present invention will be described with reference to the accompanying drawings. Further, like reference numerals will be given to like parts having substantially the same functions, and redundant description thereof will be provided only when necessary.

<First Preferred Embodiment>

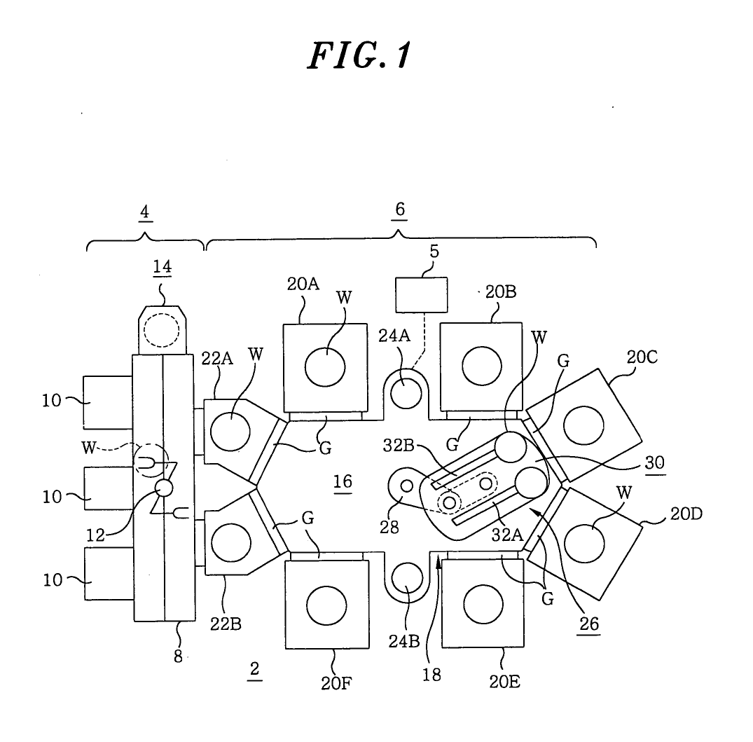

FIG. 1 is a schematic plan view showing a semiconductor processing system using a transfer mechanism in accordance with a first preferred embodiment of the present invention.

As shown in FIG. 1, a semiconductor processing system 2 mainly includes an entrance side transfer section 4 and a processing section 6. An entire operation of the processing system 2 is controlled by a controller 5.

The entrance side transfer section 4 has a longitudinally extended entrance side transfer chamber 8. Disposed at one side of the entrance side transfer chamber 8 are a plurality of port apparatuses 10 (e.g., three in this example) in each of which a cassette capable of accommodating therein a multiplicity of semiconductor wafers W as substrates to be processed is installed. Provided inside the entrance side transfer chamber 8 is a transfer mechanism 12 having, e.g., two multi-joint arms, that is movable along a length direction thereof. The two multi-joint arms can transfer the wafer W held by a pick of each leading end thereof. Further, disposed at one end portion of the entrance side transfer chamber 8 is a positioning apparatus 14 for performing a positioning by recognizing a notch or an orientation flat of the wafer W.

Meanwhile, the processing section 6 has a common transfer chamber 16 formed air-tightly by a latitudinally extended case 18. A plurality of processing apparatuses (e.g., six in this example) 20A to 20F are connected to the common transfer chamber 16 via respective gate valves G. Further, two load-lock chambers 22A and 22B are connected to the common transfer chamber 16 via respective gate valves G. The load-lock chambers 22A and 22B are connected to a sidewall of a long side of the entrance side transfer chamber 8, and the wafer W is loaded or unloaded therethrough. A vacuum exhaust unit and a N₂ gas supply unit (not shown) are connected to each of the load-lock chambers 22A and 22B so that an inner pressure thereof can be controlled to be set at a level between an atmospheric pressure and a vacuum.

Installed inside the common transfer chamber 16 are a plurality of, e.g., two, buffer tables 24A and 24B for temporarily mounting thereon the wafer W and having a cooling function or a preheating function. The vacuum exhaust unit and the N₂ gas supply unit (not shown) are also connected to the common transfer chamber 16 so that the inner pressure thereof can be controlled. A transfer mechanism 26 for transferring the wafer W is provided in the common transfer chamber 16.

A transfer mechanism 26 includes a revolvable, bendable and stretchable multi-joint arm 28 installed at a central portion of the common transfer chamber 16. A transfer base 30 is revolvably mounted on a leading end portion of the multi-joint arm 28. A plurality of support arms (e.g., two in this example) 32A and 32B are slidably provided on the transfer base 30.

Specifically, the multi-joint arm 28 is driven by using a well-known timing belt and the like. A magnetic seal or the like is installed at a bent portion and a revolving portion of the multi-joint arm 28, thereby maintaining an airtightness of an inner space.

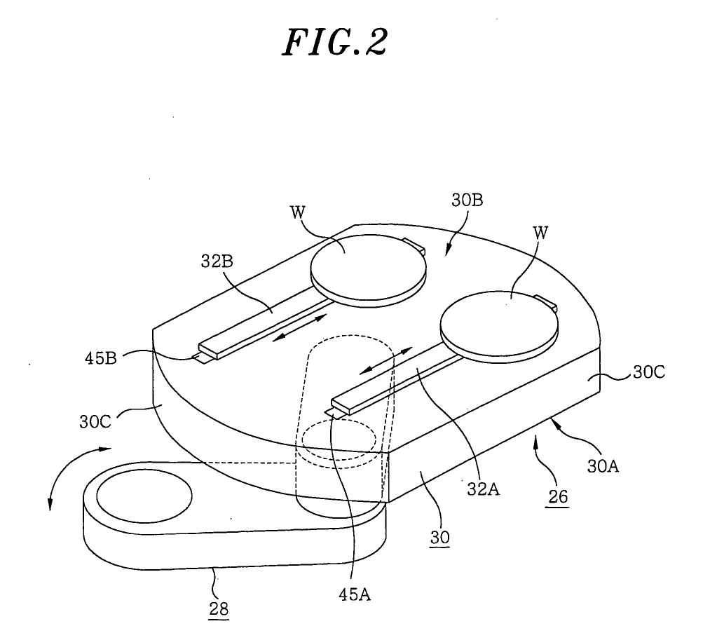

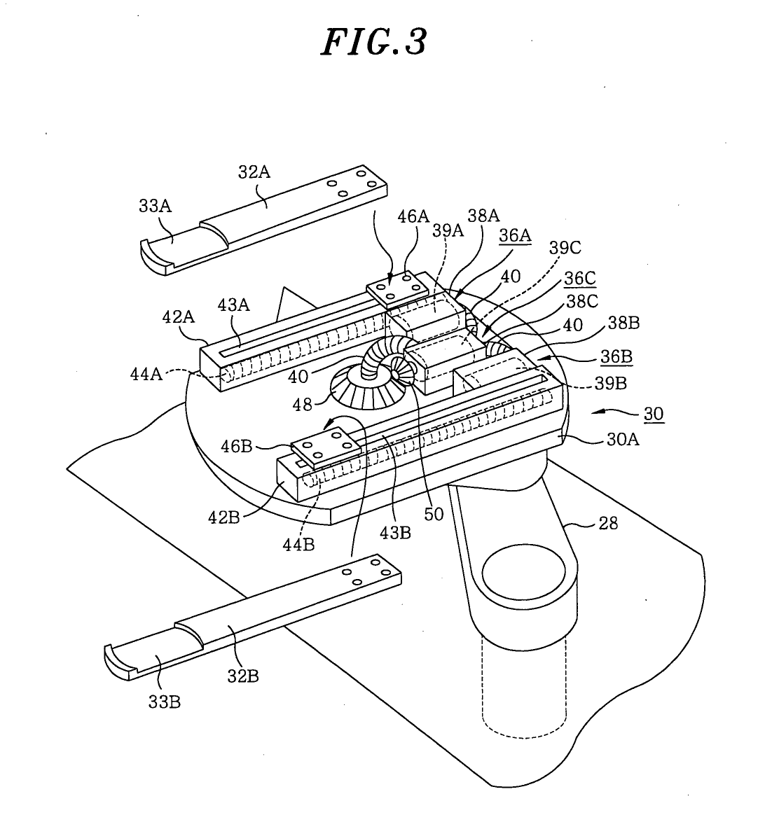

FIGS. 2 and 3 are an enlarged perspective view of the transfer mechanism illustrated in FIG. 1 and a perspective view showing an internal structure thereof, respectively. As shown in FIGS. 2 and 3, the hollow transfer base 30 includes a bottom plate 30A, a ceiling plate 30B and side plates 30C installed around a peripheral portion thereof. Further, the ceiling plate 30B and the side plates 30C are omitted in FIG. 3.

Provided on the bottom plate 30A are driving sources 36A and 36B for driving the support arms 32A and 32B, respectively, and a driving source 36C for driving the transfer base 30. The driving sources 36A to 36C respectively include electric motors 39A to 39C, e.g., step motors, accommodated respectively in airtight boxes 38A to 38C. Air-tightly connected to each of the airtight boxes 38A to 38C are pliable airtight flexible tubes 40, each being made of a bellows-shaped stainless tube, Teflone (a registered mark) tube or the like, into which a power supply cable is inserted. The flexible tubes 40 pass through the multi-joint arm 28 via through holes provided at a central portion of the bottom plate 30A and then are outwardly withdrawn. Openings of the through holes are air-tightly sealed, so that each of the electric motors 39A to 39c can rotate without being exposed to a vacuum atmosphere.

Guide rails 42A and 42B, which are in parallel with each other, are provided along with the driving sources 36A and 36B, respectively. Guide slits 43A and 43B are formed on the guide rails 42A and 42B along a length direction thereof, respectively. Provided on the ceiling plate 30B are guide slits 45A and 45B (see FIG. 2) corresponding to the guide slits 43A and 43B, respectively.

Placed in parallel at lower portions of the guide rails 42A and 42B are ball screws 44A and 44B rotated by powers of the driving sources 36A and 36B, respectively. Sliders 46A and 46B, which are upwardly protruded after passing through the guide slits 43A and 43B, are coupled to the ball screws 44A and 44B by screws, respectively. By forwardly and reversely rotating the ball screws 44A and 44B, the sliders 46A and 46B move forward or backward along the guide slits 43A and 43B, respectively. Base end portions of the support arms 32A and 32B are fixed on the sliders 46A and 46B by screws, respectively.

Formed at leading ends of the support arms 32A and 32B are recesses for picking up the wafers W. The recesses form support surfaces 33A and 33B for mounting thereon the wafers W. The support surfaces 33A and 33B of the support arms 32A and 32B are positioned on a same plane. The support arms 32A and 32B operate such that the support surfaces 33A and 33B are projected from the transfer base 30 toward a same side.

Fixedly installed around an insertion through hole of the bottom plate 30A is a bevel gear 48. The bevel gear 48 is engaged with a bevel gear 50 installed along a rotational axis of the driving source 36C. By forwardly and reversely rotating the driving source 36C, the entire transfer base 30 can be revolved left and right. Magnetic seals (not illustrated) for maintaining an airtightness are interposedly installed at through portions where the rotational axes of the electric motors 39A to 39C penetrate the airtight boxes 38A to 38C, respectively.

Hereinafter, an operation of a semiconductor processing system configured as described above will be described.

First of all, a basic flow of the semiconductor wafer W will be described with reference to FIG. 1. An unprocessed semiconductor wafer W is unloaded from a cassette mounted on the port apparatus 10 by the transfer mechanism 12 in the entrance side transfer chamber 8. After a position of the wafer W is determined in the positioning apparatus 14, the wafer W is accommodated in one load-lock chamber, e.g., the load-lock chamber 22A, by the transfer mechanism 12.

After a pressure in the load-lock chamber 22A being regulated, the load-lock chamber 22A is made to communicate with the common transfer chamber 16 previously maintained in a vacuum state. Next, by operating the transfer mechanism 26, required processes are successively carried out while the wafer being mounted and transferred among the processing apparatuses 20A to 20F as desired. When the processes for the wafer W are completed, the processed wafer W is unloaded along a same path as described above performed in a reversed sequence.

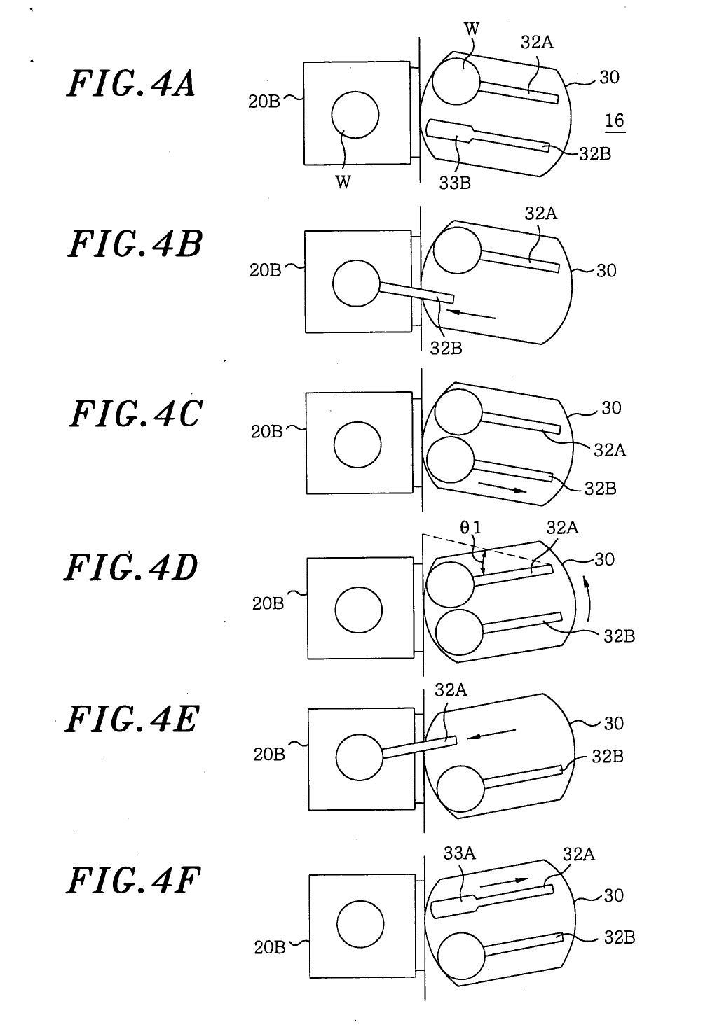

FIGS. 4A to 4F depict plan views illustrating an operation of the transfer mechanism shown in FIG. 1. Herein, a case that the wafers W are exchanged in the processing apparatus 20B is illustrated. It is assumed that the unprocessed wafer W is held on the support surface 33A of the support arm 32A, whereas the support surface 33B of the support arm 32B is empty. Further, as described above, the operation of the transfer mechanism 26 is controlled by the controller 5.

First, in order to move the transfer base 30 right in front of the desired processing apparatus 20B, the multi-joint arm 28 supporting the transfer base 30 is stretched, bent and revolved. Accordingly, the transfer base 30 is positioned right in front of the processing apparatus 20B. Thereafter, in order to make the transfer base 30 face toward the processing apparatus 20B, the driving source 36C illustrated in FIG. 3 is operated. The driving source 36C rotates the bevel gear 50 and the bevel gear 48 on the bottom plate 34A forwardly or reversely, and thus the transfer base 30 is revolved to face toward a loading/unloading port of the processing apparatus 20B (see FIG. 4A).

Then, the driving source 36B is operated to slide the support arm 32B forward along the guide slit 43B. Further, the support surface 33B of a leading end of the support arm 32B is made to enter the processing apparatus 20B to receive the processed wafer W on the support surface 33B (see FIG. 4B). Next, the driving source 36B is rotated reversely to slide the support arm 32B backward, thereby restoring the support surface 33B. Accordingly, the processed wafer W is loaded into the common transfer chamber 16 (see FIG. 4C).

Thereafter, the driving source 36C is operated to make the other support arm 32A face toward a center of the processing apparatus 20B. Further, the transfer base 30 is revolved to rotate the entire transfer base 30 by a predetermined angle of θ1 (see FIG. 4D).

Next, the driving source 36A is operated to slide the support arm 32A forward along the guide slit 43A. Then, the unprocessed wafer W held on the support surface 33A of the leading end of the support arm 32A is made to enter the processing apparatus 20B to be mounted and transferred into the processing apparatus 20B (see FIG. 4E). Thereafter, the driving source 36A is reversely rotated to slide the support arm 32A backward and restore the support surface 33A. Accordingly, the support arm 32A is withdrawn into the common transfer chamber 16 (see FIG. 4F).

In this manner, the operation for exchanging the wafers W is completed. Since the support arms 32A and 32B are slidable in a same direction, the wafers W can be exchanged only by slightly rotating the transfer base 30, thereby improving a throughput.

As described above, in this embodiment, the support arms 32A and 32B are linearly slid relative to the transfer base 30 so that the semiconductor wafers W can be exchanged. Therefore, positioning accuracy or reproducibility of the positioning accuracy can be improved. Further, due to a relatively simple configuration, reliability or maintainability can also be improved.

The electric motors 39A to 39C are respectively surrounded by the airtight boxes 38A to 38C in an airtight state. Accordingly, it is possible to prevent particles generated from each of the electric motors 39A to 39C from being adhered to the wafer W.

In case of the operation illustrated in FIGS. 4A to 4F, the entire transfer base 30 is rotated by an angle of θ1 in the middle of the operation so that positions of the support arms 32A and 32B are changed relative to the processing apparatus 20B. That is, in this case, the transfer base 30 is stopped after being inclined at a predetermined angle relative to the processing apparatus 20B.

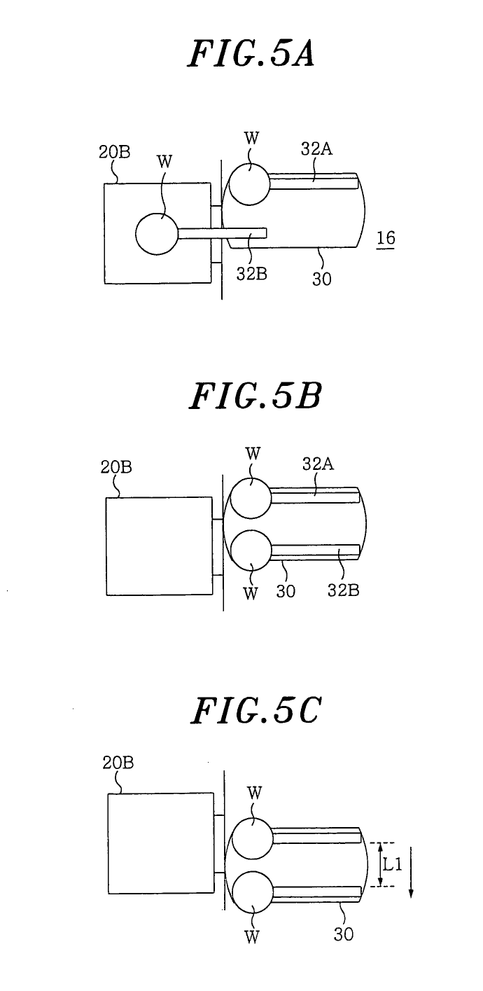

FIGS. 5A to 5C present plan views illustrating an exemplary modification of the operation for exchanging the semiconductor wafers, which is performed by using the transfer mechanism 26 shown in FIG. 1. In case of an operation illustrated in FIGS. 5A to 5C, positions of the support arms 32A and 32B relative to the processing apparatus 20B are changed by a linear movement of the transfer base 30, not by a rotation thereof. In other words, in such case, the transfer base 30 is stopped without being inclined relative to the processing apparatus 20B. Further, as described above, the operation of the transfer mechanism 26 is controlled by the controller 5.

First of all, the transfer base 30 is disposed such that the empty support arm 32B faces the loading/unloading port of the processing apparatus 20B. Then, the support arm 32B is slid forward to receive the processed wafer W in the processing apparatus 20B (see FIG. 5A). Next, the support arm 32B is slid backward to carry the processed wafer W into the common transfer chamber 16 (see FIG. 5B).

Thereafter, the entire transfer base 30 is translated by a distance L1 in parallel with a front surface of the processing apparatus 20B. Accordingly, the transfer base 30 is positioned so that the support arm 32A holding the unprocessed wafer W faces the loading/unloading port of the processing apparatus 20B (see FIG. 5C). Next, the support arm 32A is slid forward so that the unprocessed wafer W is mounted and transferred into the processing apparatus 20B.

In case of such operation, the translation of the transfer base 30 is carried out by stretching, bending and revolving the multi-joint arm 28 to have the translation distance L1. At this time, the driving source 36C illustrated in FIG. 3 is slightly operated so that the transfer base 30 can face in one direction, thereby compensating a self rotation of the transfer base 30, which results from a stretch, a bend and a revolution of the multi-joint arm 28.

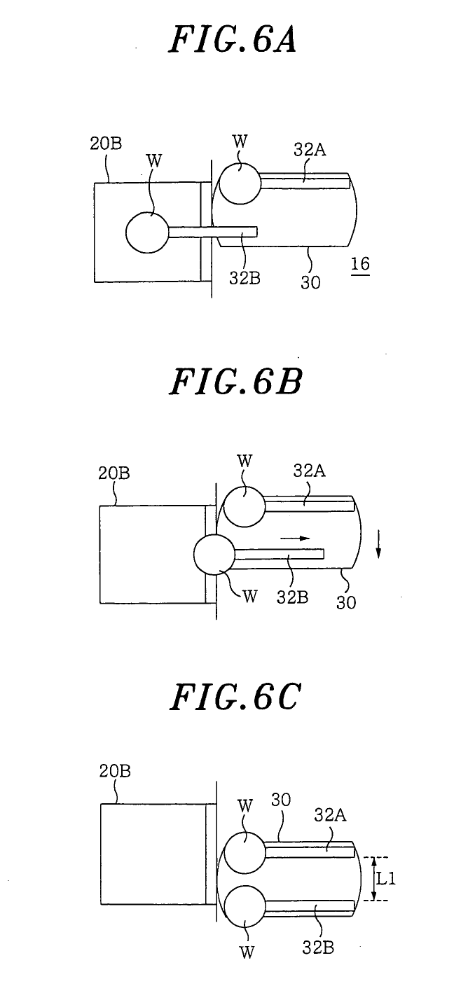

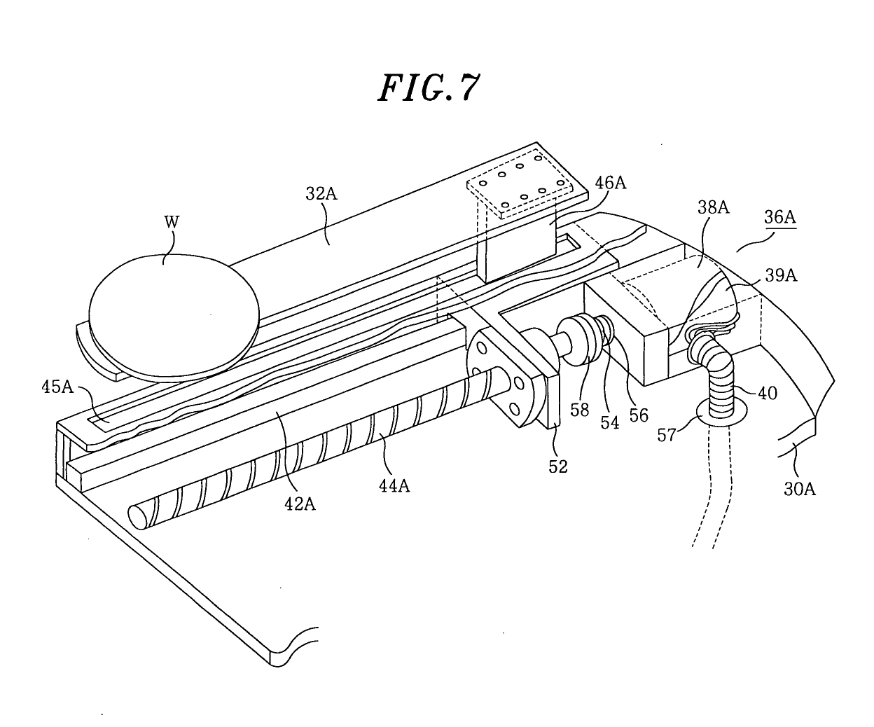

The operation shown in FIGS. 5A to 5C includes respective steps sliding the support arm 32B and translating the transfer base 30. In regard to this point, as illustrated in FIGS. 6A to 6C, the movement of the support arm 32B and the transfer base 30 can be simultaneously performed.

FIGS. 6A to 6C represent plan views showing an exemplary modification of the operation for exchanging the semiconductor wafers W, which is performed by using the transfer mechanism 26 illustrated in FIG. 1. Further, as described above, the operation of the transfer base 30 is controlled by the controller 5.

First of all, the transfer base 30 is positioned such that the empty support arm 32B faces the loading/unloading port of the processing apparatus 20B. Next, the support arm 32B is slid forward to receive the processed wafer W in the processing apparatus 20B (see FIG. 6A).

Thereafter, the support arm 32B is slid backward and, at the same time, the entire transfer base 30 is translated in parallel with the front surface of the processing apparatus 20B (see FIG. 6B). Accordingly, the processed wafer W is carried into the common transfer chamber 16 and, at the same time, the transfer base 30 is positioned such that the support arm 32A holding the unprocessed wafer W faces the loading/unloading port of the processing apparatus 20B (see FIG. 6C).

In case of the operation shown in FIGS. 6A to 6C, the slide of the support arm 32B and the translation of the transfer base 30 are simultaneously performed. Therefore, it is possible to save time required for the exchanging operation and, accordingly, improve the throughput. In the same manner, in case of the operation illustrated in FIGS. 4A to 4F, the slide of the support arms 32A and 32B and the revolution of the transfer base 30 can be simultaneously performed under the control of the controller 5. Accordingly, the same effects as aforementioned can be obtained.

FIG. 7 provides a perspective view illustrating an exemplary modification of a driving unit of the support arm in the transfer mechanism shown in FIG. 1. In case of a structure depicted in FIG. 3, the guide rails 42A and 42B and the ball screws 44A and 44B are vertically placed in parallel. In case of a structure shown in FIG. 7, the guide rails and the ball screws are horizontally placed in parallel. Further, since a guide rail and the proximity thereto have the same structure at both sides, the guide rail 42A as an example will be described with reference to FIG. 7.

As shown in FIG. 7, the guide rail 42A is formed to have a rectangular-shaped cross section. The slider 46A capable of sliding along the guide rail 42A is disposed thereabove. A frame 52 is extended from the slider 46A in a horizontal direction, and a base end portion of the ball screw 44A is rotatably attached to the frame 52. The ball screw 44A is extended in parallel with the guide rail 42A.

The electric motor 39A is accommodated in the airtight box 38A of the driving source 36A. A rotational axis 54 of the motor 39A outwardly penetrates via a magnetic seal 56. The rotational axis 54 is connected to the base end portion of the ball screw 44A by a coupling ring 58 so that the ball screw 44A can be rotated forwardly and reversely. Further, the flexible tube 40 may be installed to penetrate the bottom plate 30A via a sealing member 57.

Also in such structure, the support arm 32A can be linearly slid by operating the driving source 36A.

In the semiconductor processing system illustrated in FIG. 1, the six processing apparatuses 20A to 20F are connected to the horizontally lengthened common transfer chamber 16. In case of a small number of the processing apparatuses, e.g., four, the common transfer chamber 16 can be formed in a shape of an approximate regular hexagon. FIG. 8 shows a schematic plan view illustrating an exemplary modification of the semiconductor processing system from such point of view.

As depicted in FIG. 8, four processing apparatuses, e.g., the processing apparatuses 20A to 20D, and two load-lock chambers 22A and 22B are connected to the approximately regular hexagon shaped common transfer chamber 16. The transfer mechanism 26 does not include the multi-joint arm 28 (see FIG. 1), and only the transfer base 30 is revolvably positioned at the central portion of the common transfer chamber 16. Upon loading or unloading the wafer, the transfer base 30 can access each of the processing apparatuses 20A to 20D and load-lock chambers 22A and 22B only by revolving it.

<Second Preferred Embodiment>

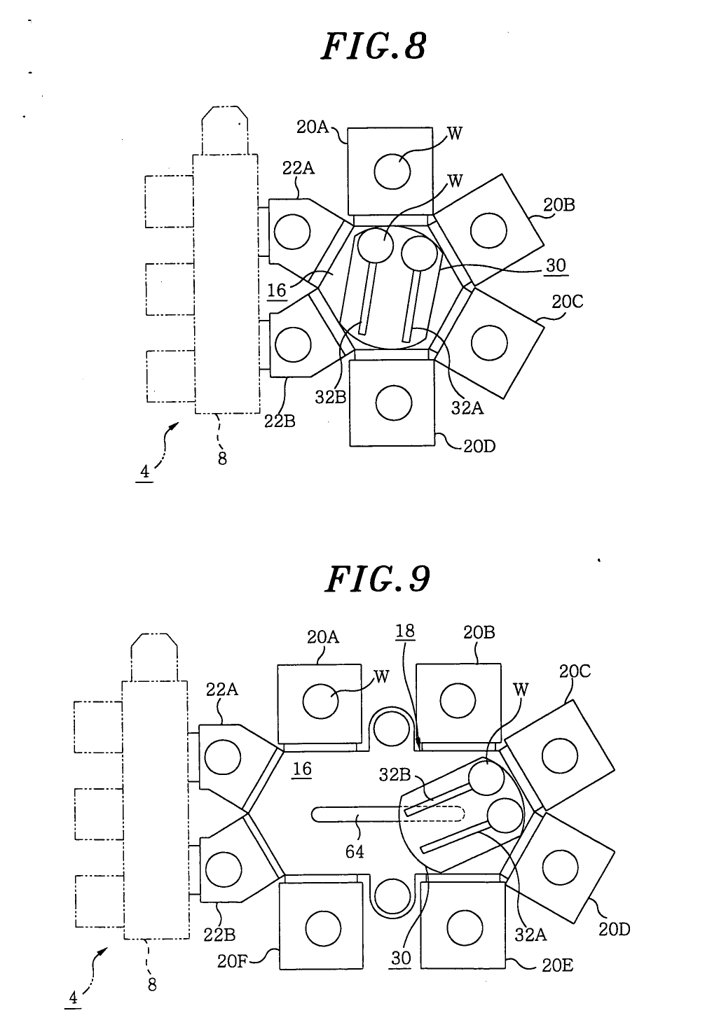

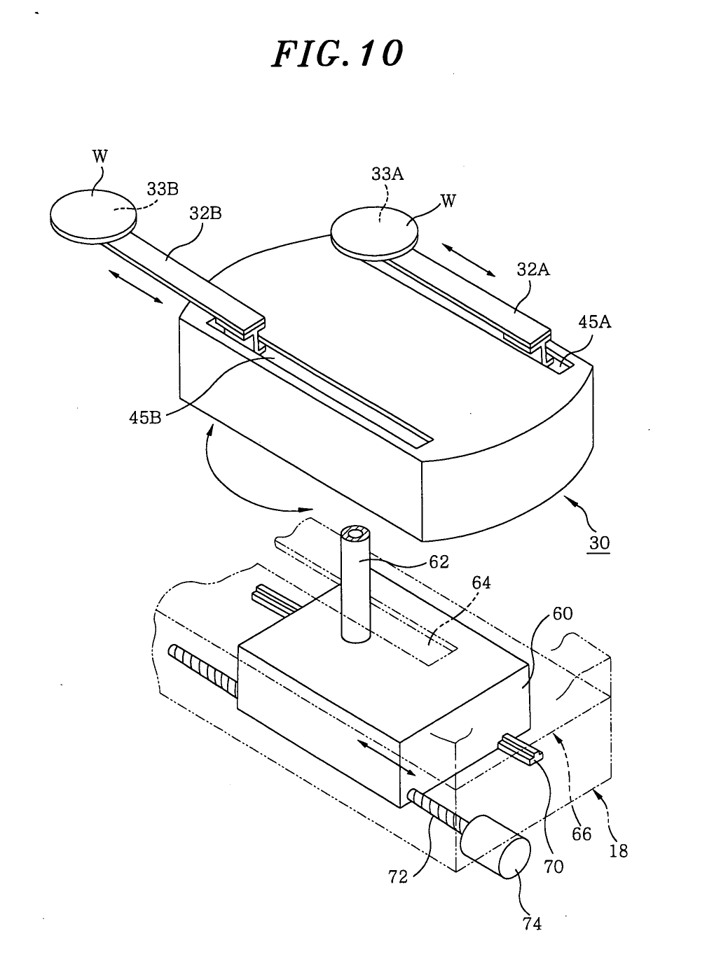

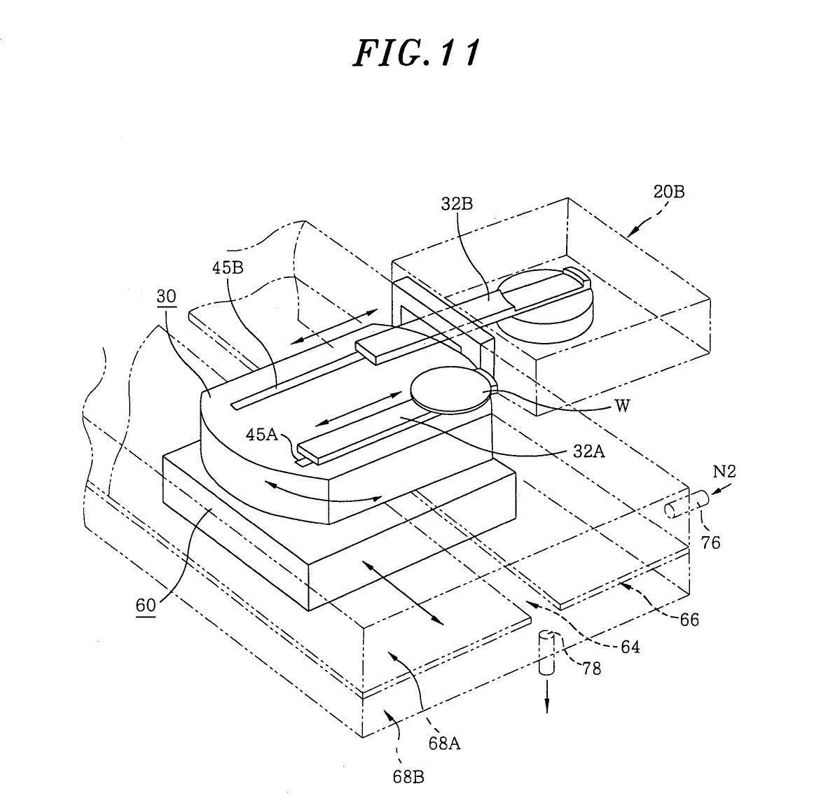

FIG. 9 is a schematic plan view showing a semiconductor processing system using a transfer mechanism in accordance with a second preferred embodiment of the present invention. FIG. 10 describes a perspective view illustrating a conjugated state of a transfer base and a moving table in the transfer mechanism shown in FIG. 9. FIG. 11 offers a perspective view illustrating an operation for exchanging the semiconductor wafers W, which is performed by using the transfer mechanism shown in FIG. 9.

In the processing system illustrated in FIG. 1, the transfer base 30 moves in a length direction of the common transfer chamber 16 by stretching and bending the multi-joint arm 28 of the transfer mechanism 26. It is possible to move the transfer base 30 by using another device, e.g., a ball screw mechanism, instead of the multi-joint arm 28. The transfer mechanism illustrated in FIG. 9 reflects such point of view.

As shown in FIGS. 10 and 11, in the transfer mechanism 26 in accordance with the second preferred embodiment, the transfer base 30 is conjugated to a linearly movable moving table 60 via a hollow coupling axis 62. The transfer base 30 is rotatably supported by the pivoting coupling axis 62. The flexible tube 40 illustrated in FIG. 3 is inserted into the hollow coupling axis 62.

An inner portion of the case 18 forming the common transfer chamber 16 is divided into two upper and lower spaces 68A and 68B by a sectional plate 66. A guide slit 64 is formed on the sectional plate 66 along a length direction thereof to move the coupling axis 62. The moving table 60 and the transfer base 30 are respectively provided inside the lower space 68B and the upper space 68A.

The guide rail 70 is positioned in the lower space 68B to guide the moving table 60 along a length direction thereof. A ball screw 72 is provided in parallel with the guide rail 70. By forwardly and reversely rotating the ball screw 72, the moving table 60 can be moved forward and backward. In order to rotate the ball screw 72, a driving source (a motor) 74 is provided at an outside of the case 18. A magnetic seal (not shown) is installed at a portion where the ball screw 72 penetrates the case 18.

As shown in FIG. 11, provided on a sidewall of the upper space 68A is a gas nozzle 76 for introducing an inert gas or a N₂ gas. Formed on a bottom portion of the lower space 68B is a gas exhaust port 78 for evacuating an inner atmosphere. An atmospheric gas in the upper space 68A is exhausted after flowing into the lower space 68B via the guide slit 64.

In accordance with the second preferred embodiment, the ball screw 72 is rotated to move the moving table 60 linearly. At this time, the transfer base 30 unitedly connected to the moving table 60 via the coupling axis 62 also moves with the moving table 60 in the common transfer chamber 30 along a length direction thereof.

In case of this embodiment, the transfer base 30 is linearly moved by the ball screw mechanism without using the multi-joint arm 28 illustrated in FIG. 1. Accordingly, it is possible to further improve the positioning accuracy or the reproducibility of the positioning accuracy. Further, due to a simple structure of the ball screw mechanism, the reliability or the maintainability can also be further improved.

In addition, in the first and the second embodiment, a linear motor may be used as a mechanism for linearly moving the support arms 32A and 32B or the transfer base 30.

<Third Preferred Embodiment>

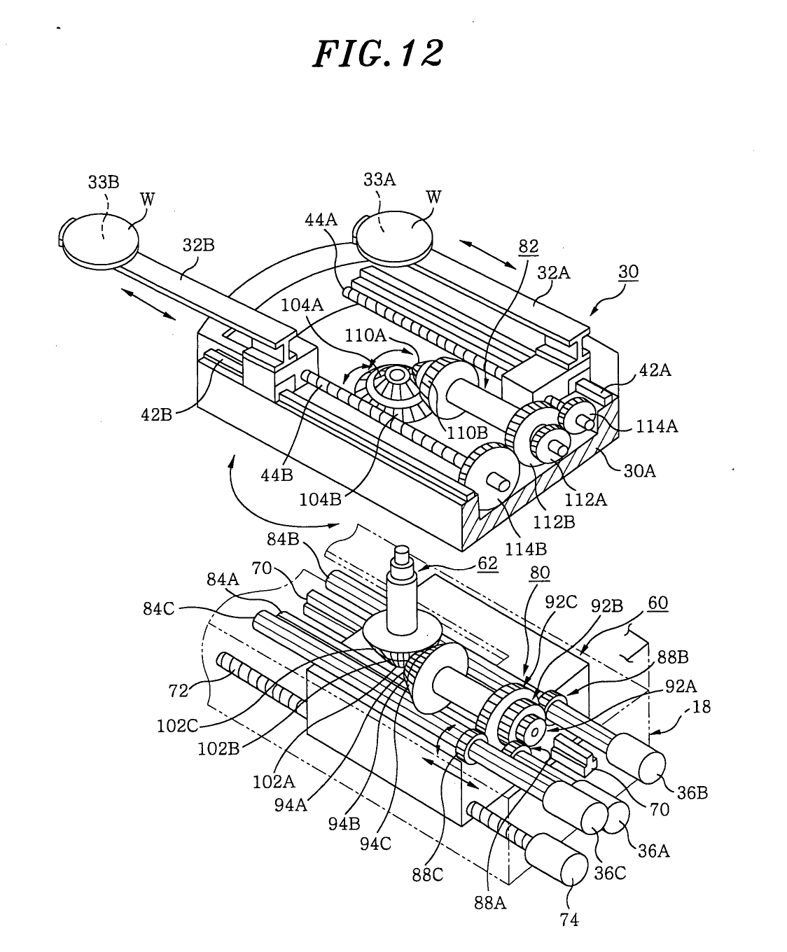

FIG. 12 sets forth an exploded perspective view showing an internal structure of a transfer mechanism in accordance with a third preferred embodiment of the present invention. Further, a ceiling plate of the transfer base is omitted in FIG. 12.

In the aforementioned first and second preferred embodiments, the slide of the support arms 32A and 32B and the rotation of the transfer base 30 are carried out by driving forces of the driving sources 36A and 36B and the driving source 36C installed adjacent thereto, respectively. However, it is possible to install each of the driving sources 36A to 36C outside the common transfer chamber and transfer the driving forces of the driving sources 36A to 36C by a gear mechanism. The transfer mechanism illustrated in FIG. 12 reflects such point of view.

As depicted in FIG. 12, the driving sources (motors) 36A, 36B, 36C and 74 for respectively driving the support arms 32A and 32B, the transfer base 30 and the moving table 60 are disposed outside a sidewall of the case 18 forming the common transfer chamber 16. In order to transfer the driving forces from the driving sources 36A to 36C, a first gear mechanism 80 is provided inside the moving table 60. In order to transfer the driving forces from the driving sources 36A and 36B, a second gear mechanism 82 is provided inside the transfer base 30.

Specifically, three spline axes 84A to 84C extending along a moving direction of the moving table 60 are connected to the driving sources 36A to 36C, respectively. The spline axes 84A to 84C are extended in parallel to one another while penetrating the moving table 60. Magnetic seals (not shown) and the like are interposedly installed at through portions where the spline axes 84A to 84C penetrate the case 18, respectively, to maintain an airtightness in the case 18.

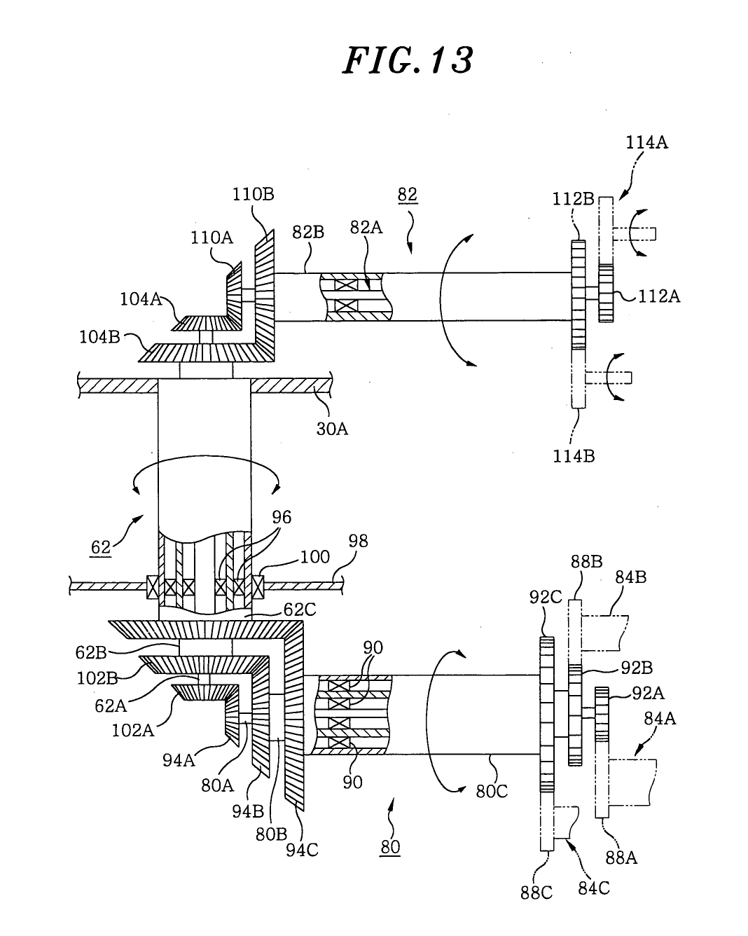

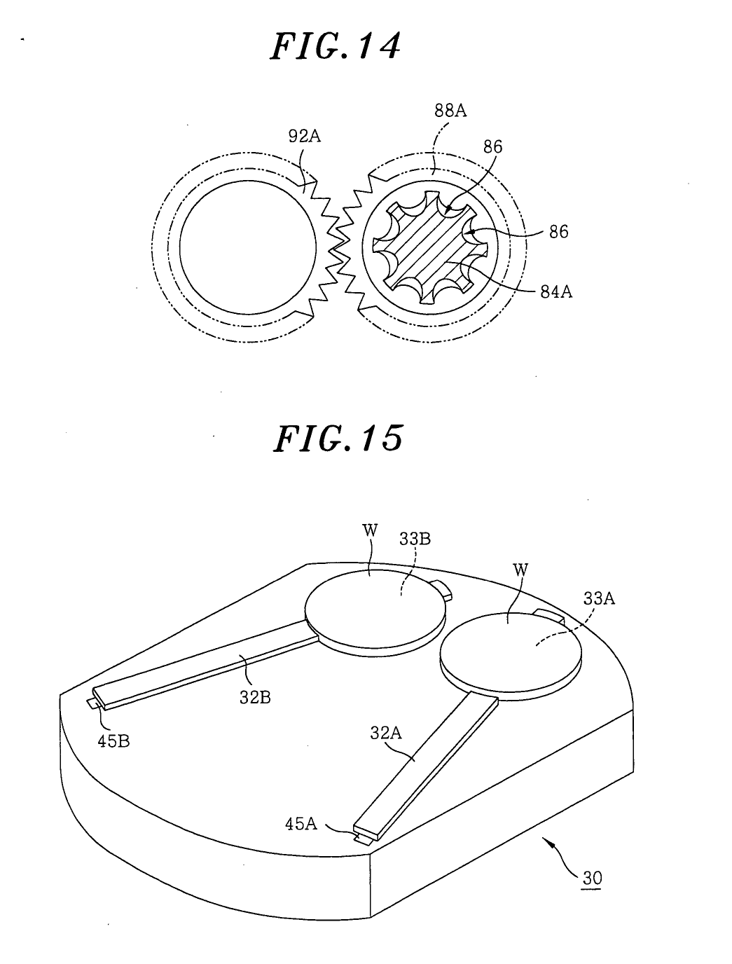

FIG. 13 schematically illustrates a connected state of the gear mechanisms in the transfer mechanism illustrated in FIG. 12. FIG. 14 shows a relationship between the spline axis and the gear in the transfer mechanism illustrated in FIG. 12.

As can be seen from the spline axis 84A representatively illustrated in FIG. 14, respectively formed at the spline axes 84A to 84C are slits 86 extending along a length direction thereof. The spline axes 84A to 84C are respectively fitted in gears 88A to 88C (see FIG. 12). The gears 88A to 88C are engaged with the slits 86 in order to restrict the spline axes 84A to 84C in a rotational direction and, at the same time, to be slidable along a length direction thereof. Each of the gears 88A to 88C is rotatably supported on the moving table 60 and moves together with the moving table 60.

As described in FIG. 13, the first gear mechanism 80 accommodated in the moving table 60 has a three-axis coaxial structure having a central axis 80A positioned at a center, an intermediate axis 80B and an outer axis 80C positioned at an outside thereof. Bearings 90 are interposed between the axis 80A and the axis 80B and between the axis 80B and the axis 80C, respectively, and each of the axes 80A to 80C becomes rotatable. Further, the outer axis 80C is rotatably supported on the moving table 60.

Each of gears 92A to 92C is fixedly attached to one end portion of each of the axes 80A to 80C. The gears 92A to 92C are respectively engaged with the gears 88A to 88C slidably inserted into the spline axes 84A to 84C. Thus, each rotation of the gears 88A to 88C moves a corresponding one of the gears 92A to 92C. Further, gears 94A to 94C, e.g., bevel gears, are fixedly attached to the other end portions of the axes 80A to 80C, respectively”.

As shown in FIG. 13, the coupling axis 62 perpendicular to the moving table 60 has a three-axis coaxial structure having a central axis 62A positioned at a center, an intermediate axis 62B and an outer axis 62C positioned at an outside thereof. Bearings 96 are interposed between the axis 62A and the axis 62B and between the axis 62B and the axis 62C, and each of the axes 62A to 62C becomes rotatable. Further, the outer axis 62C is rotatably supported on a ceiling plate 98 via a bearing 100.

Gears 102A to 102C, e.g., bevel gears, are fixedly attached to bottom portions of the axes 62A to 62C, respectively. Each of the gears 102A to 102C is engaged with a corresponding one of the gears 94A to 94C of the first gear mechanism 80. Therefore, the rotation of the gears 94A to 94C of the first gear mechanism 80 moves the gears 102A to 102C, respectively. Gears 104A and 104B, e.g., bevel gears, are fixedly attached to upper portions of the inner two axes 62A and 62B among the three axes 62A to 62C. An upper portion of the outer axis 62C is directly fixed on the bottom plate 30A of the transfer base 30, so that the outer axis 62C can rotate together with the transfer base 30.

As shown in FIG. 13, the second gear mechanism 82 provided inside the transfer base 30 has a two-axis coaxial structure having a central axis 82A disposed at a central portion and an outer axis 82B positioned at a peripheral portion thereof. A bearing 108 is interposed between the axis 82A and the axis 82B, and each of the axes 82A and 82B becomes rotatable. The outer axis 82B is rotatably supported on the transfer base 30.

Fixedly attached to one end portion of each of the axes 82A and 82B is a corresponding one of gears 110A and 110B, e.g., a bevel gear. The gears 110A and 110B are respectively engaged with the gears 104A and 104B provided at an upper portion of the coupling axis 62, each being capable of transferring a rotational force separately. Gears 112A and 112B are fixedly attached to the other end portions of the axes 82A and 82B, respectively.

Referring back to FIG. 12, there are illustrated gears 114A and 114B fixedly attached to base end portions of the ball screws 44A and 44B placed in parallel with the two support arms 32A and 32B, respectively. The gears 114A and 114B are respectively engaged with the gears 112A and 112B of the second gear mechanism 82.

In the transfer mechanism shown in FIG. 12, the driving source 74 is driven to rotate the ball screw 72, thereby linearly moving the moving table 60 and the transfer base 30 together. Such operation is same as that described in the second preferred embodiment with reference to FIG. 10.

In order to revolve the transfer base 30, the driving source 36C is operated. A rotational driving force of the driving source 36C is transferred to the gear 92C of the first gear mechanism 80 via the spline 84C and the gear 88C. The gear 92C rotates the outer axis 80C and the gear 94C provided at the other end portion unitedly. Such rotational force is transferred to the gear 102C of a lower portion of the coupling axis 62. Since the upper portion of the outer axis 62C is unitedly fixed on the transfer base 30, the outer axis 62C is rotated to simultaneously rotate the transfer base 30.

In order to slide the support arm 32A or 32B, the driving source 36A or 36B is operated. For example, a rotational driving force of the driving source 36A of the support arm 32A is transferred to the gear 88A via the spline axis 84A. Such rotational driving force is transferred to the gear 102A of the lower portion of the coupling axis 62, the central axis 62A and the gear 104A of and the upper portion via the gear 92A of the first gear mechanism 80, the central axis 80A and the gear 94A. Further, such rotational driving force is sequentially transferred to the gear 110A of one end portion of the second gear mechanism 82, the central axis 80A and the gear 112A of the other end portion thereof.

The gear 112A is engaged with the gear 114A of an end portion of the ball screw 44A. Accordingly, by forwardly and reversely rotating the ball screw 44A with the help of a rotation of the gear 112A, the support arm 32A can be slid. In the ball screw 44B and the support arm 32B of the other side, a driving force is transferred along a power transfer path as mentioned above.

In revolving the transfer base 30, the followings should be noted. The gears 104A and 104B of the upper portion of the coupling axis 62 are respectively engaged with the gears 110A and 110B of the second gear mechanism 82. Thus, when only the transfer base 30 is revolved while the driving sources 36A and 36B are stopped, the gears 110A and 110B are rotated as well. As a result, the support arms 32A and 32B are moved forward or backward as rotated. In order to prevent such phenomena, the driving sources 36A and 36B are reversely rotated to compensate the forward or the backward rotation described above. In this way, only the transfer base 30 can be rotated without making the support arms 32A and 32B slide relative to the transfer base 30.

Further, in case of the third preferred embodiment, an operation for exchanging the wafers can be performed as described with reference to FIGS. 4A to 4F, 5A to 5C, or 6A to 6C. Furthermore, in the gear mechanism illustrated in FIGS. 13 and 14, a portion for sliding the support arms 32A and 32B and a portion for revolving the transfer base 30 can be applied to a case where spline axes are not used, e.g., the transfer mechanism illustrated in FIG. 10.

As described above, in the third preferred embodiment, unlike the first and the second preferred embodiment, the driving sources 36A to 36C are provided outside the case 18, and driving forces of the driving sources are transferred via the gear mechanisms 80 and 82 and the coupling axis 62. Accordingly, there is no need to install a timing belt or a harness that emits the large amount of gas and deteriorates heat resistance, or a driving source (a motor) in a vacuum, thereby enabling an improvement of a vacuum level. Moreover, the number of particles generated can be reduced, and a heat resistant temperature can be increased. In addition, since motors are centralized and disposed at one spot, the maintainability of the motors can be improved. Besides, a wiring operation can be easily performed and, therefore, there is no need for the flexible tubes 40 illustrated in FIG. 3, for inserting the power supply cable therethrough.

In the first to third preferred embodiments, the two support arms 32A and 32B are placed in parallel on the transfer base 30. In regard to this point, an arrangement type of the support arms 32A and 32B can be varied, as will be described hereinafter.

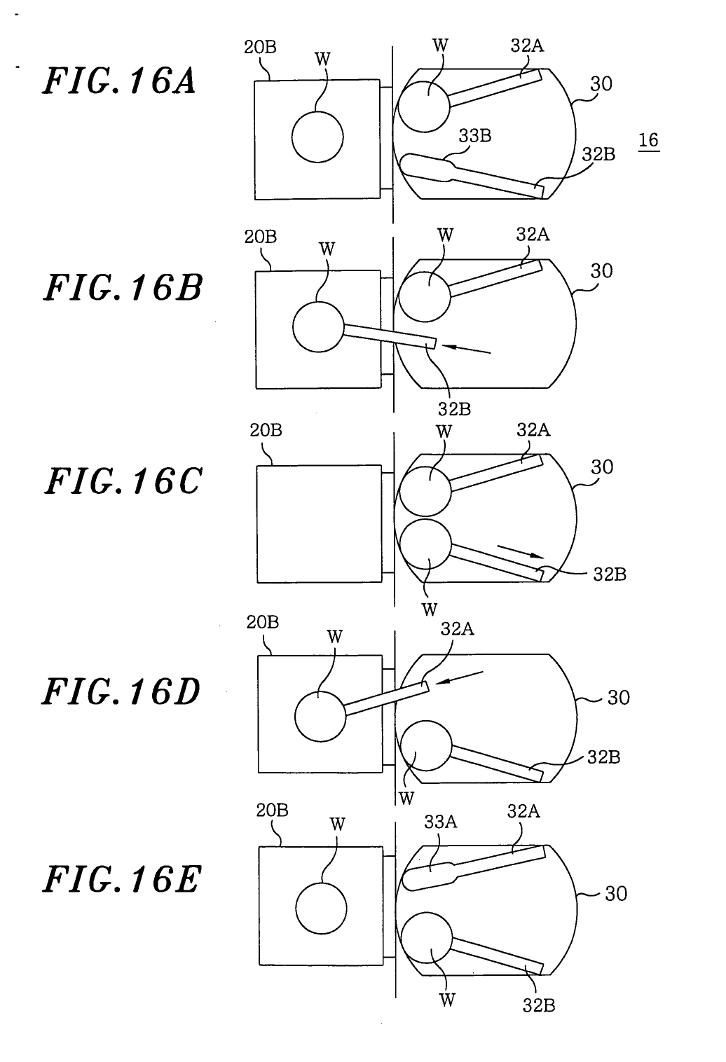

FIG. 15 provides an enlarged perspective view illustrating an exemplary modification of the transfer mechanism. FIGS. 16A to 16E present plan views showing an operation for exchanging the semiconductor wafers W, which is performed by using the transfer mechanism illustrated in FIG. 15.

In case of such exemplary modification, the two support arms 32A and 32B slide along converging directions when projected from the transfer base 30. The support surfaces 33A and 33B formed at leading ends of the support arms 32A and 32B are positioned on a same plane. The support surfaces 33A and 33B occupy a same position when loading or unloading the wafer W into or from a mounting table of the processing apparatus by being projected from the transfer base 30.

In this case, as illustrated in FIGS. 16A to 16E, after the transfer base 30 is aligned relative to, e.g., the processing apparatus 20B, the wafers W can be exchanged without moving the transfer base 30. That is, first of all, the transfer base 30 is positioned in front of a desired processing apparatus (see FIG. 16A). Next, by using the support arm 32B, the processed wafer W is carried from the processing apparatus 20B into the common transfer chamber 16 (see FIGS. 16B and 16C). Thereafter, by using the support arm 32A, an unprocessed wafer W is mounted and transferred from the common transfer chamber 16 into the processing apparatus 20B (see FIGS. 16D and 16E).

In such an operation, unlike the aforementioned preferred embodiment, it is possible to exchange the wafers W while the transfer base 30 being fixed without having the transfer base 30 to be revolved or translated in the middle of the operation. Accordingly, the exchanging operation is quickly performed, so that the throughput can be improved.

<Fourth Preferred Embodiment>

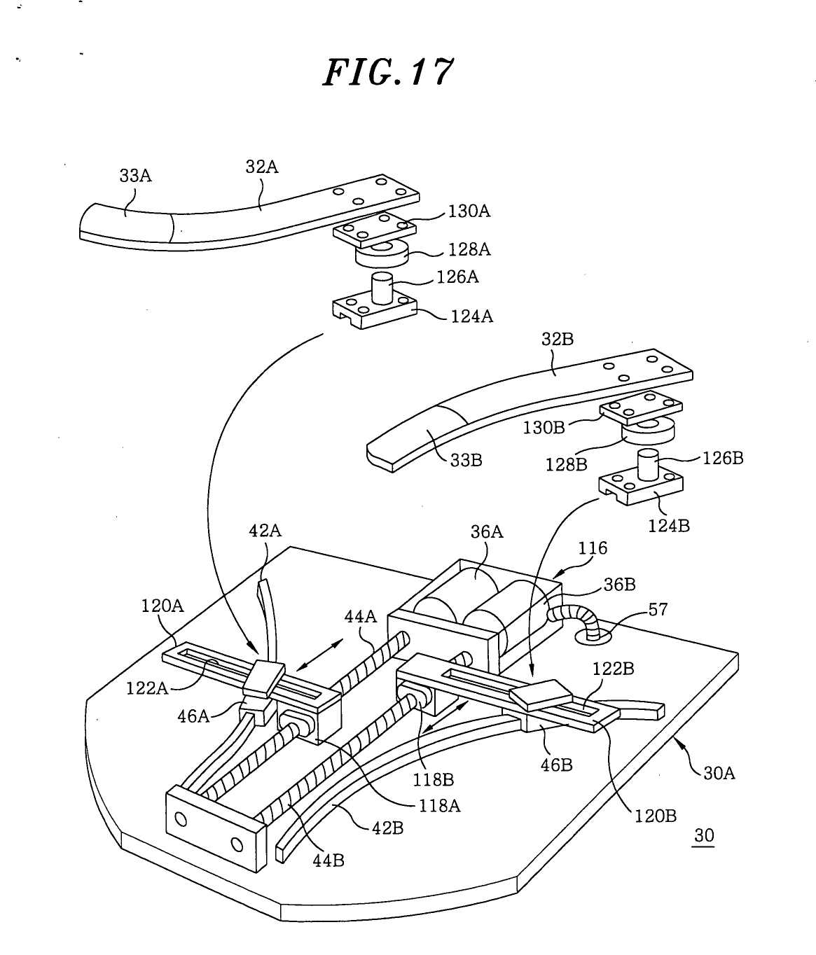

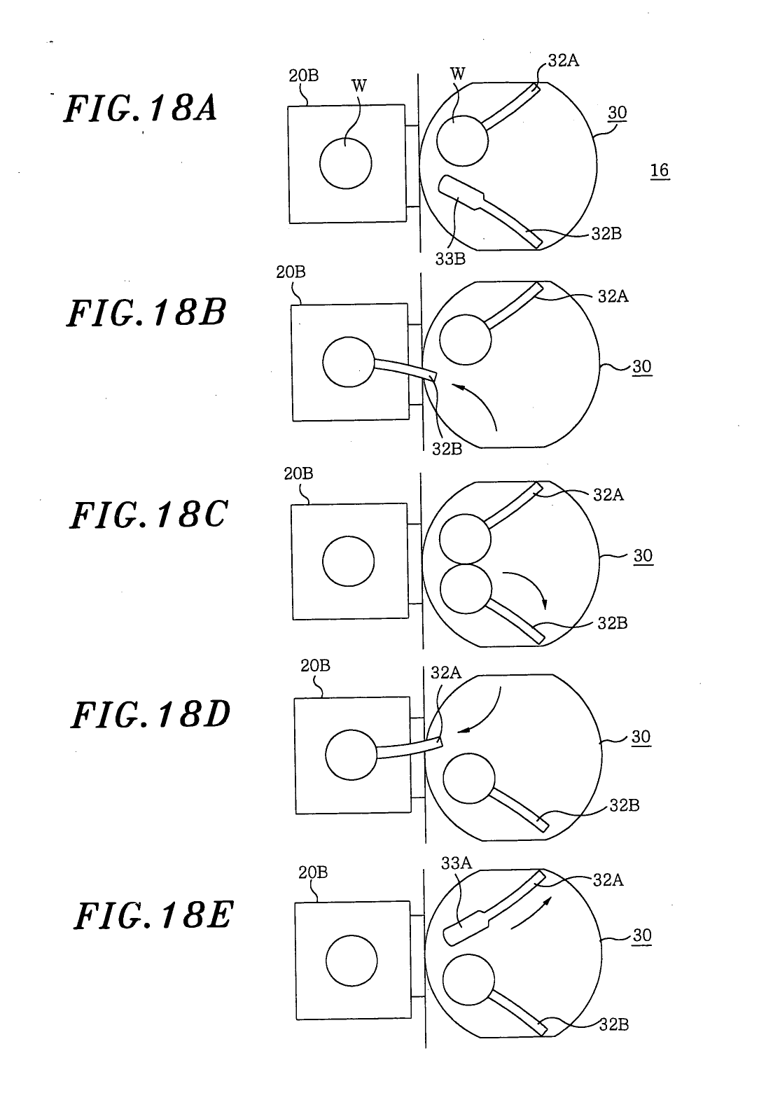

FIG. 17 is an exploded perspective view showing an internal structure of a transfer mechanism in accordance with a fourth preferred embodiment of the present invention. FIGS. 18A to 18E represent plan views describing an operation for exchanging the semiconductor wafers W, which is performed by using the transfer mechanism illustrated in FIG. 17. Further, herein, the ceiling plate, the driving source and related members of the transfer base 30 are omitted.

In the first to third preferred embodiments, the guide rails 42A and 42B (see FIG. 3) for respectively guiding the support arms 32A and 32B are formed in a linear shape. In regard to this point, such guide rails can be formed in a shape of a substantially circular arc. The transfer mechanism illustrated in FIG. 17 reflects such point. Further, the shape of the substantially circular arc indicates that a curvature thereof is locally different.

As depicted in FIG. 17, both driving sources 36A and 36B and the ball screws 44A and 44B are centralized at a central portion. Both driving sources 36A and 36B are accommodated in one airtight box 116. Provided at both sides of the ball screws 44A and 44B are the approximate circular arc-shaped guide rails 42A and 42B that are symmetrically bent in opposite directions. Conjugated to the guide rails 42A and 42B are the sliders 46A and 46B that are slidable therealong.

Nuts 118A and 118B are respectively attached to the ball screws 44A and 44B. Beams 120A and 120B having a length capable of covering an entire region of the guide rails 42A and 42B are respectively extended from the nuts 118A and 118B toward the guide rails 42A and 42B. Respectively formed at the beams 120A and 120B are guide slits 122A and 122B extending along a length direction thereof.

In the meantime, the sliders 46A and 46B respectively include slider bases 124A and 124B being in a direct contact with the guide rails 42A and 42B thereabove. Pins 126A and 126B stand on the slider bases 124A and 124B. Rollers 128A and 128B are rotatably attached to the pins 126A and 126B which are movably inserted thereinto. Attachments 130A and 130B are fixedly attached to respective top portions of the pins 126A and 126B by screws and the like.

The rollers 128A and 128B attached to the pins 126A and 126B are inserted into the guide slits 122A and 122B of the beams 120A and 120B, respectively. In such state, each of the attachments 130A and 130B is fixed on a corresponding top portion of the pins 126A and 126B. Base end portions of the support arms 32A and 32B are fixedly attached to the attachments 126A and 126B, respectively, by using screws and the like. It is preferable to form each of the support arms 32A and 32B in a shape of the approximately circular arc as a corresponding one of the guide rails 42A and 42B.

In accordance with the fourth preferred embodiment, as the ball screws 44A and 44B are rotated, the beams 120A and 120B move along the ball screws 44A and 44B, respectively. At this time, since the rollers 128A and 128B rotate within the guide slits 122A and 122B, the sliders 46A and 46B can move along a length direction of the guide slits 122A and 122B, respectively. As a result, the support arms 32A and 32B can slide along the approximately circular arc-shaped guide rails 42A and 42B in an approximate same direction, i.e., toward the same processing apparatus.

Further, the support surfaces 33A and 33B of the leading ends of the support arms 32A and 32B are positioned on a same plane. The support surfaces 33A and 33B occupy a same position when loading or unloading the wafer W into or from a mounting table of the processing apparatus by being projected from the transfer base 30.

Also in the fourth preferred embodiment, as illustrated in FIGS. 18A to 18E, after the transfer base 30 is aligned relative to, e.g., the processing apparatus 20B, the wafers W can be exchanged without moving the transfer base 30. In other words, above all, the transfer base 30 is positioned right in front of a desired processing apparatus (see FIG. 18A). Next, by using the support arm 32B, a processed wafer W is carried from the processing apparatus 20B to the common transfer chamber 16 (see FIGS. 18B and 18C). Thereafter, by using the support arms 32A, an unprocessed wafer W is mounted and transferred from the common transfer chamber 16 to the processing apparatus 20B (see FIGS. 18D and 18E).

According to such operation, unlike the aforementioned preferred embodiment, the wafers W can be exchanged while the transfer base 30 being fixed without having the transfer base 30 to be revolved or translated the middle of the operation. Accordingly, the exchanging operation is quickly performed, so that the throughput can be improved.

Further, since the support arms 32A and 32B are slid in the approximately circular arc shape, a size of a loading/unloading port of the processing apparatus 20B can be reduced. Therefore, it is possible to scale-down a size of gate valves used in the loading/unloading ports of the processing apparatus 20B.

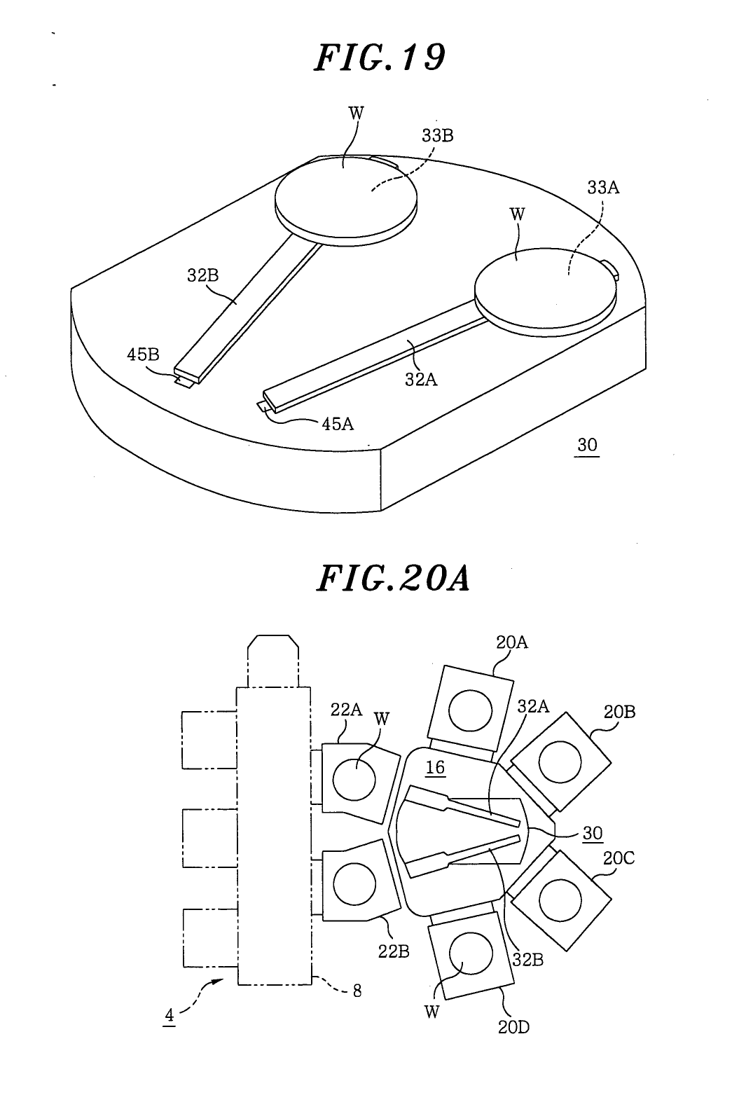

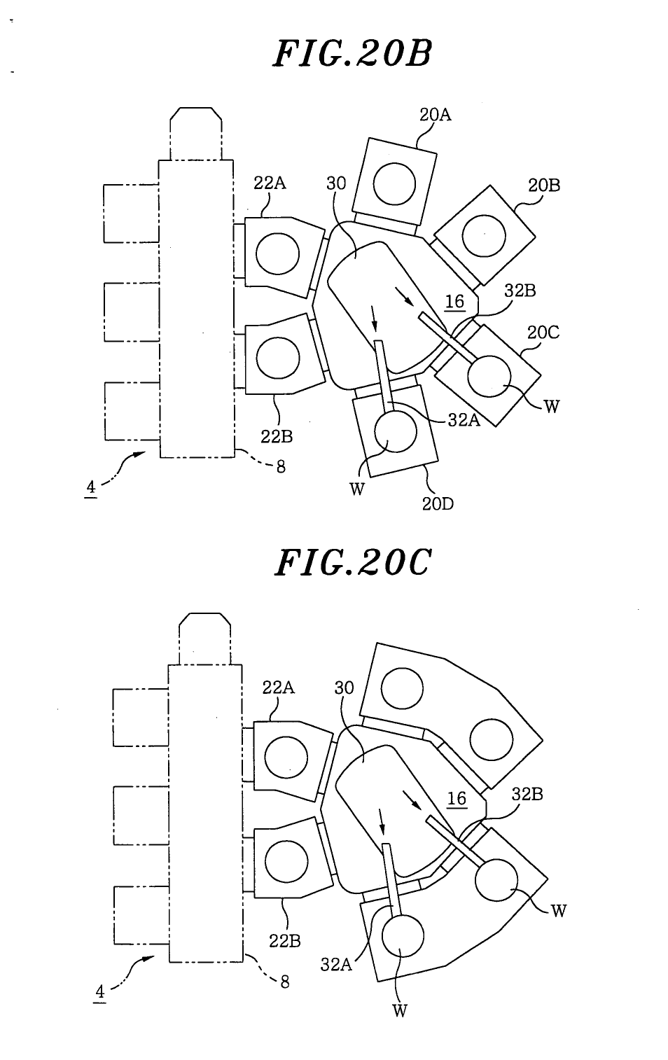

FIG. 19 depicts an enlarged perspective view illustrating an exemplary modification of the transfer mechanism. FIGS. 20A and 20B provide schematic plan views showing a semiconductor processing system using the transfer mechanism described in FIG. 19.

In the transfer mechanism shown in FIGS. 15 and 17, the two support arms 32A and 32B are slid along converging directions when projected from the transfer base 30. In regard to this point, in case of such exemplary modification, the two support arms 32A and 32B are slid along diverging directions when projected from the transfer base 30. The support surfaces 33A and 33B formed at leading ends of the support arms 32A and 32B are positioned on a same plane.

As illustrated in FIGS. 20A and 20B, the common transfer chamber 16 is formed in a shape of an approximate equilateral triangle. Adjacently connected to each side of the common transfer chamber 16 are the processing apparatuses 20A and 20B, the processing apparatuses 20C and 20D and load-lock chambers 22A and 22B, respectively. The transfer base 30 is rotatably provided at a central portion of the common transfer chamber 16.

A direction of extending the both support arms 32A and 32B is set in such a way that the support arms 32A and 32B face two adjacent processing apparatuses, e.g., the processing apparatuses 20A and 20B; the processing apparatuses 20C and 20D; and the load-lock chambers 22A and 22B, as illustrated in FIGS. 20A and 20B. Therefore, as shown in FIGS. 20A and 20B, wafers W can be simultaneously obtained from two processing apparatuses or two load-lock chambers and, further, mounted and transferred to other portions at the same time.

Moreover, as illustrated in FIG. 20C, the transfer mechanism illustrated in FIG. 19 can be applied to a semiconductor processing system including a processing chamber apparatus 21 in which two wafers W are loaded into a single processing chamber side by side.

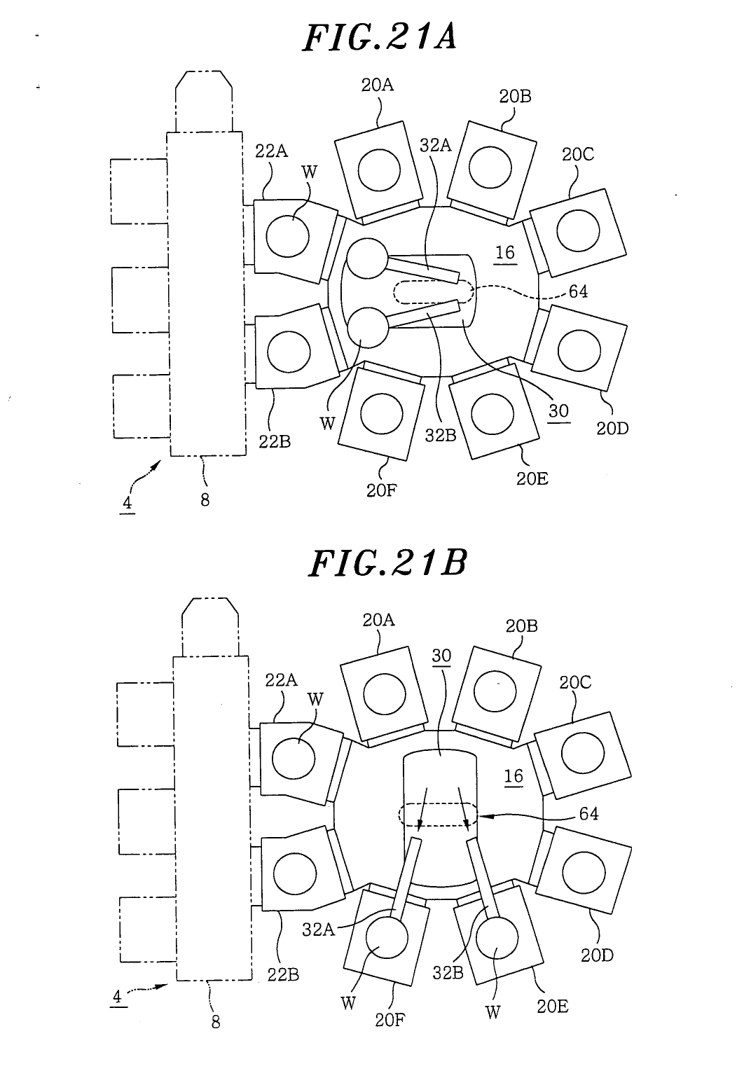

FIGS. 21A and 21B set forth schematic plan views showing another semiconductor processing system using the transfer mechanism illustrated in FIG. 19.

As shown in FIGS. 21A and 21B, the common transfer chamber 16 is formed in a shape of a horizontally lengthened hexagon. Adjacently connected to each side of the common transfer chamber 16 are the processing apparatuses 20A and 20B, the processing apparatuses 20C and 20D, the processing apparatuses 20E and 20F and the load-lock chambers 22A and 22B. Disposed at a central portion of the common transfer chamber 16 is the transfer base 30 illustrated in FIG. 19 capable of translating along a length direction thereof. As for a mechanism for translating the transfer base 30, it may use either the multi-joint arm 28 shown in FIG. 1 or the moving table 60 illustrated in FIG. 10. In this case, it is also possible to simultaneously access two processing apparatuses or two load-lock chambers.

Further, in the transfer mechanism illustrated in FIG. 19, a case where support arms 32A and 32B access two processing apparatuses is described. However, as shown in FIGS. 4A to 4F, the transfer mechanism depicted in FIG. 19 can be also applied to a case where an unloading of a processed wafer and a loading of an unprocessed wafer are sequentially performed in a single processing apparatus. In comparing this with a case of using the transfer mechanism shown in FIG. 2, the amount of revolution of the transfer base 30 increases, thereby deteriorating the throughput to a certain extent. However, in comparison of this with a conventional transfer mechanism in which arms are stretched and bent toward two different directions (in opposite directions, i.e., 180 degrees away), a sufficiently higher throughput can be obtained.

Furthermore, the aforementioned arrangement types of the two support arms 32A and 32B on the transfer base 30, i.e., a parallel illustrated in FIG. 2, a convergence illustrated in FIG. 15, an arc shown in FIG. 17 and a divergence depicted in FIG. 18, can be selectively applied to any of processing systems of FIGS. 1, 8, 9, 20A to 20C and, 21A and 21B. Further, each arrangement type of the support arms 32A and 32B can be applied to other processing systems apart from those illustrated in the above-described drawings.

<Related Arts>

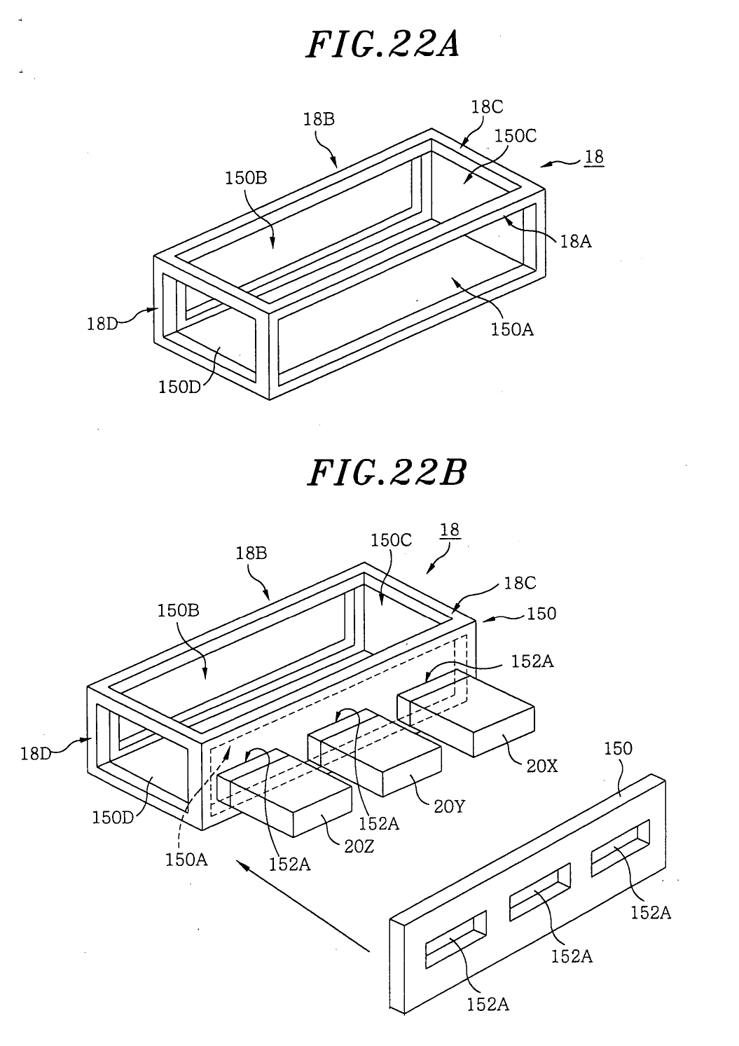

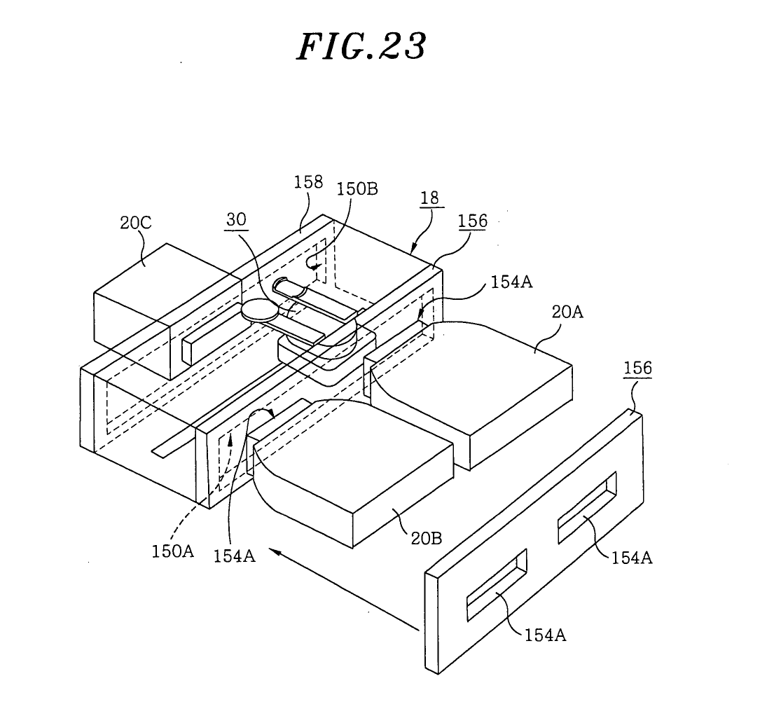

FIGS. 22A, 22B and 23 depict perspective views showing a common transfer chamber for explaining related arts.

Generally, in case of designing the common transfer chamber, there is a need to determine design criteria such as the number, a size and an attachment position of a processing apparatus. Conventionally, after such design criteria are determined, the aforementioned common transfer chamber is assembled and then, e.g., a manufacturing of an opening for attaching a processing apparatus to a side plate thereof is directly performed. Further, the processing apparatus and the like are fixedly attached to the side plate directly. However, it takes a large amount of time to complete the apparatus.

Therefore, in this related art, an opening of a large aperture is previously provided at a side plate, a ceiling plate or the like of the case 18 for bordering the common transfer chamber 16, and the case 18 is formed by assembling thereof. Meanwhile, a processing apparatus mounting plate on which a loading/unloading port is formed is prepared to be attached or detached to or from a side plate, a ceiling plate or the like of the case 18 by using bolts and the like. A plurality of the processing apparatus mounting plates is prepared in advance. Each of the processing apparatus mounting plates is provided in advance with different-sized or different-numbered loading/unloading ports. After the design criteria are determined, if processing apparatus mounting plates corresponding thereto are used, an assembly of the apparatus can be quickly performed.

In an exemplary apparatus illustrated in FIGS. 22A and 22B, large openings 150A to 150D are respectively formed at side plates 18A and 18B of a length direction of the case 18; a ceiling plate 18C; and a side plate 18D provided at a short side that is opposite to the length direction. A plurality of such cases 18 is formed in advance regardless of the above-described design criteria. As depicted in FIG. 22B, when the design criteria are determined by an order and the like, a processing apparatus mounting plate 150 corresponding thereto is fixedly attached to the side plates 18A, 18B and 18D or the ceiling plate 18C by using bolts and the like.

FIG. 22B illustrates a state that the processing apparatus mounting plate 150 is attached to the side plate 18A. Disposed at the processing apparatus mounting plate 150 are loading/unloading ports for attaching a processing apparatus. In FIG. 22B, three loading/unloading ports 152A are provided. Small-sized processing apparatuses 20X, 20Y and 20Z are respectively attached to the loading/unloading ports 152A. A plurality of such processing apparatus mounting plates 150 are provided in advance. Further, the number or the size of the loading/unloading ports 152A is different depending on a plate. Moreover, the processing apparatus mounting plate 150 selected in accordance with the design criteria determined by the order and the like is used. In addition, herein, although an opening 150C is provided on the ceiling plate 18C, it may be possible to employ a single plate without the opening 150C.

In an exemplary apparatus shown in FIG. 23, a processing apparatus mounting plate 156 having two large-sized loading/unloading ports 154A is fixedly attached to the side plate 18A provided at one side of the length direction of the case 18 by using bolts and the like. A processing apparatus mounting plate 158 having a single loading/unloading port (not shown) is fixedly attached to the other side plate 18B by using bolts and the like. Attached to one processing apparatus mounting plate 156 are two large-sized processing apparatuses 20A and 20B. Attached to the other processing apparatus mounting plate 158 is a single large-sized processing apparatus 20C.

As described above, if there are provided in advance a plurality of processing apparatus mounting plates 150, 156 and 158 having differently numbered or differently sized loading/unloading ports for each plate, it is possible to simply and quickly attach a side plate having a loading/unloading port of a proper size corresponding to an order. Further, the shape of the common transfer chamber is not limited to a rectangle but can be a pentagon, a hexagon or a polygon having more sides.

Although a semiconductor wafer W has been described as a substrate to be processed in aforementioned preferred embodiments, the present invention is not limited thereto but can be applied to a glass substrate, an LCD substrate and the like.

While the invention has been shown and described relative to the preferred embodiments, it will be understood by those skilled in the art that various changes and modifications may be without departing from the spirit and scope of the invention as defined in the following claims.

1. A transfer mechanism for transferring substrates to be processed with respect to a processing apparatus in a semiconductor processing system, the transfer mechanism comprising:
a transfer base;
a support for supporting the transfer base; and
a first and a second support arm disposed on the transfer base,
wherein the support includes a stretchable and bendable arm that is stretchable and bendable, and
wherein the first and the second support arm respectively have a first and a second support surface for holding the substrates to be processed; the first and the second support surface are positioned on a substantially same plane; and the first and the second support arm are operated such that the first and the second support surface are projected from the transfer base toward a substantially equivalent side.

2.

3.

4. The transfer mechanism of claim 1, wherein a first and a second driving motor for respectively sliding the first and the second support arm and a third driving motor for revolving the transfer base are disposed at an outside of the transfer base, and an axis for revolving the transfer base with respect to the support has a three-axis coaxial structure for transferring driving forces of the first to the third driving motors.

5. A transfer mechanism for transferring substrates to be processed with respect to a processing apparatus in a semiconductor processing system, the transfer mechanism comprising:
a transfer chamber air-tightly formed by a case;
a sectional plate disposed in the transfer chamber to form a first and a second space therein;
a transfer base disposed in the first space;
a moving table, disposed in the second space, for linearly moving the transfer base;
a guide rail, disposed in the second space, for guiding the moving table along a length direction of the guide rail;
a driving mechanism for moving the moving table along the guide rail;
a gas exhaust port, formed at a bottom portion of the second space, for evacuating an internal atmosphere of the second space; and
a first and a second support arm disposed on the transfer base,
wherein the first and the second support arm respectively have a first and a second support surface for holding the substrates to be processed; the first and the second support surface are positioned on a substantially same plane; and the first and the second support arm are operated such that the first and the second support surface are projected from the transfer base toward a substantially equivalent side.

6. (Canceled)

7. The transfer mechanism of claim 6, wherein the first and the second chamber are surrounded by a case; a first and a second driving motor for respectively sliding the first and the second support arm and a third driving motor for revolving the transfer base are disposed at an outside of the case; and the transfer base is connected with the moving body by the coupling axis having a three-axis coaxial structure for transferring driving forces of the first to the third driving motors.

8.

9. A transfer mechanism for transferring substrates to be processed relative to a processing apparatus in a semiconductor processing system, the transfer mechanism comprising:
a transfer base; and
a first and a second support arm disposed on the transfer base,
wherein the first and the second support arm respectively have a first and a second support surface for holding the substrates to be processed; the first and the second support surface are positioned on a substantially same plane; the first and the second support arm are operated such that the first and the second support surface are projected from the transfer base toward a substantially equivalent side; and the first and the second support surface slide along substantially circular arcs.

10. The transfer mechanism of claim 1, wherein the first and the second support surface slide along substantially circular arcs, and the first and the second support surface occupy a same position when being in a state projected from the transfer base.

11. The transfer mechanism of claim 1 or 5, wherein the first and the second support surface slide along directions converging toward each other when projected from the transfer base.

12. The transfer mechanism of claim 1, wherein the first and the second support arm slide along directions converging toward each other when projected from the transfer base, and the first and the second support surface occupy a same position when being in a state projected from the transfer base.

13. The transfer mechanism of claim 1 or 5, wherein the first and the second support surface slide along directions diverging from each other when projected from the transfer base.

14. (Canceled)

15. (Canceled)

16. (Canceled)

17. A semiconductor processing system comprising:
a common transfer chamber;
a plurality of processing apparatuses connected in parallel to the common transfer chamber; and
a transfer mechanism, disposed in the common transfer chamber, for transferring substrates to be processed relative to the processing apparatuses,
wherein the transfer mechanism includes:
a transfer base;
a support for supporting the transfer base; and
a first and a second support arm disposed on the transfer base,
wherein the support includes a stretchable and bendable arm that is stretchable and bendable, and
wherein the first and the second support arm respectively have a first and a second support surface for holding the substrates to be processed; the first and the second support surface are positioned on a substantially same plane; and the first and the second support arm are operated such that the first and the second support surface are projected from the transfer base toward a substantially equivalent side.

18. The semiconductor processing system of claim 17, further comprising an evacuable load-lock chamber connected in parallel with the processing apparatuses to the common transfer chamber, which is also evacuable.

19. The semiconductor processing system of claim 17, wherein the first and the second support surface slide along substantially circular arcs, and the first and the second support surface occupy a same position when being in a state projected from the transfer base.

20. The semiconductor processing system of claim 17, wherein the first and the second support surface slide along directions converging toward each other when projected from the transfer base, and the first and the second support surface occupy a same position when being in a state projected from the transfer base.

21. The semiconductor processing system of claim 17, wherein the first and the second support surface slide along directions diverging from each other when projected from the transfer base.

22. (Canceled)

23. The semiconductor processing system of claim 17, further comprising a controller for controlling the transfer mechanism to simultaneously revolve the transfer base and slide at least one of the first and the second support arm.

24. The semiconductor processing system of claim 17, wherein the transfer base is linearly movable and
the semiconductor processing system further comprising a controller for controlling the transfer mechanism to simultaneously make a linear motion of the transfer base and operate at least one of the first and the second support arm.

25. A transfer mechanism for transferring substrates to be processed relative to a processing apparatus in a semiconductor processing system, the transfer mechanism comprising:
a multi-joint arm;
a first and a second support arm disposed at a leading end of the multi-joint arm; and
driving motors, disposed on the multi-joint arm, for driving the first and the second support arm,
wherein the first and the second support arm respectively have a first and a second support surface for holding the substrates to be processed; the first and the second support surface are positioned on a substantially same plane; and the first and the second support arm are operated such that the first and the second support surface are projected from the transfer base toward a substantially equivalent side.

26. A semiconductor processing system comprising:
a common transfer chamber;
a plurality of processing apparatuses connected in parallel to the common transfer chamber; and
a transfer mechanism, disposed in the common transfer chamber, for transferring substrates to be processed relative to the processing apparatuses,
wherein the transfer mechanism includes:
a multi-joint arm;
a first and a second support arm disposed at a leading end of the multi-joint arm; and
driving motors, disposed on the multi-joint arm, for driving the first and the second support arm,
wherein the first and the second support arm respectively have a first and a second support surface for holding the substrates to be processed; the first and the second support surface are positioned on a substantially same plane; and the first and the second support arm are operated such that the first and the second support surface are projected from the transfer base toward a substantially equivalent side.

27. A transfer mechanism for transferring substrates to be processed with respect to a processing apparatus in a semiconductor processing system, the transfer mechanism comprising:
a transfer base;
a support for revolvably supporting the transfer base;
a first and a second support arm disposed on the transfer base; and
a driving unit, disposed on the transfer base, for driving the first and the second support arm,
wherein the first and the second support arm respectively have a first and a second support surface for holding the substrates to be processed; the first and the second support surface are positioned on a substantially same plane; and the first and the second support arm are operated such that the first and the second support surface are projected from the transfer base toward a substantially equivalent side.

28. The transfer mechanism of claim 27, wherein the transfer base is linearly movable and
the transfer mechanism further comprising a controller for controlling the transfer mechanism to simultaneously make a linear motion of the transfer base and operate at least one of the first and the second support arm.

29. A semiconductor processing system comprising:
a common transfer chamber;
a plurality of processing apparatuses connected in parallel to the common transfer chamber; and
a transfer mechanism, disposed in the common transfer chamber, for transferring substrates to be processed with respect to the processing apparatuses,
wherein the transfer mechanism includes:
a transfer base;
a support for revolvably supporting the transfer base;
a first and a second support arm disposed on the transfer base; and
a driving unit, disposed on the transfer base, for driving the first and the second support arm,
wherein the first and the second support arm respectively have a first and a second support surface for holding the substrates to be processed; the first and the second support surface are positioned on a substantially same plane; and the first and the second support arm are operated such that the first and the second support surface are projected from the transfer base toward a substantially equivalent side.

30. The semiconductor processing system of claim 29, further comprising evacuable load-lock chambers connected in parallel with the processing apparatuses to the common transfer chamber, which is also evacuable.

31. The semiconductor processing system of claim 29, wherein the first and the second support surface slide along substantially circular arcs, and the first and the second support surface occupy a same position when being in a state projected from the transfer base.

32. The semiconductor processing system of claim 29, wherein the first and the second support surface slide along directions converging toward each other when projected from the transfer base, and the first and the second support surface occupy a same position when being in a state projected from the transfer base.

33. The semiconductor processing system of claim 29, wherein the first and the second support surface slide along directions diverging from each other when projected from the transfer base.

34. The semiconductor processing system of claim 29, further comprising a controller for controlling the transfer mechanism to simultaneously revolve the transfer base and slide at least one of the first and the second support arm.

35. The semiconductor processing system of claim 29, wherein the transfer base is linearly movable and
the semiconductor processing system further comprising a controller for controlling the transfer mechanism to simultaneously make a linear motion of the transfer base and operate at least one of the first and the second support arm.

36. The semiconductor processing system of claim 30, further comprising a controller for controlling the transfer mechanism to simultaneously unload two substrates to be processed from the load-lock chambers and simultaneously transfer and mount the two unloaded substrates to be processed onto two of the processing apparatuses.
